(19) United States
(12) Patent Application Publication
(10) Pub. No.: US 2026/0090210 A1
(43) Pub. Date: Mar. 26, 2026

(54) DISPLAY DEVICE AND ELECTRONIC DEVICE INCLUDING THE SAME

(71) Applicant: Samsung Display Co., Ltd., Yongin-si (KR)

(72) Inventors: JONG CHAN LEE, Yongin-si (KR); Jonghwan Shin, Yongin-si (KR); YONGHO YANG, Yongin-si (KR); YURI OH, Yongin-si (KR); KI-BOK YOO, Yongin-si (KR); DONGHYEOK LEE, Yongin-si (KR); KITAEK JEONG, Yongin-si (KR); YONGSEON JO, Yongin-si (KR)

(21) Appl. No.: 19/225,645

(22) Filed: Jun. 2, 2025

(30) Foreign Application Priority Data
Sep. 20, 2024 (KR) 10-2024-0127162

(51) Int. Cl. H10K 59/122

(52) U.S. Cl. CPC H10K 59/122

(57) ABSTRACT

A display device includes: a substrate including a hole area, a first non-display area surrounding at least a portion of the hole area, and a display area surrounding at least a portion of the first non-display area; pixels in the display area on the substrate; a first dam in the first non-display area on the substrate, wherein the first dam includes an alignment hole; and a first alignment pattern in the first non-display area on the first dam, wherein the first alignment pattern at least partially overlaps the alignment hole in a plan view.

### CROSS-REFERENCE TO RELATED APPLICATION

The present application claims priority to and benefit of Korean Patent Application No. 10-2024-0127162, filed on Sep. 20, 2024, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

A display device is a device that displays images for providing visual information to users. Among display devices, an organic light emitting diode display device has recently attracted attention.

As an area occupied by a display area of a display device increases, various functions are being added to the display area. For example, the display device may include a component that performs various functions while displaying images.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same. For example, aspects of some embodiments of the present disclosure relate to a display device providing visual information and an electronic device including the same.

Aspects of some embodiments of the present disclosure include a display device including an alignment pattern having a relatively improved recognition rate.

Aspects of some embodiments of the present disclosure include an electronic device including the display device.

According to some embodiments, a display device includes a substrate including a hole area, a first non-display area surrounding at least a portion of the hole area, and a display area surrounding at least a portion of the first non-display area, pixels located in the display area on the substrate, a first dam located in the first non-display area on the substrate, and a first alignment pattern located in the first non-display area on the first dam.

According to some embodiments, the first dam may include an alignment hole.

According to some embodiments, the first alignment pattern may at least partially overlap the alignment hole in a plan view.

According to some embodiments, the alignment hole may overlap one end of the first alignment pattern in the plan view.

According to some embodiments, the first dam may have a ring shape surrounding the hole area.

According to some embodiments, the alignment hole may have a ring shape surrounding the hole area.

According to some embodiments, each of the pixels may include a light-emitting element including a first electrode, a light-emitting layer located on the first electrode, and a second electrode located on the light-emitting layer.

According to some embodiments, the display device may further include a pixel defining layer covering a side portion of the first electrode.

According to some embodiments, the first dam may include a first layer, a second layer located on the first layer, and a third layer located on the second layer and including a same material as the pixel defining layer.

According to some embodiments, the third layer of the first dam may define the alignment hole.

According to some embodiments, the display device may further include an input electrode located on the light-emitting element.

According to some embodiments, the first alignment pattern and the input electrode may be located in a same layer.

According to some embodiments, the display device may further include a second dam located in the first non-display area and spaced apart from the first dam in the plan view.

According to some embodiments, the display device may further include a second alignment pattern spaced apart from the first alignment pattern and at least partially overlapping the alignment hole in the plan view.

According to some embodiments, the hole area may be located between the first alignment pattern and the second alignment pattern.

According to some embodiments, the alignment hole may overlap one end of the second alignment pattern in the plan view.

According to some embodiments, the display device may further include a third alignment pattern spaced apart from each of the first alignment pattern and the second alignment pattern in the plan view and at least partially overlapping the alignment hole in the plan view and a fourth alignment pattern spaced apart from the third alignment pattern and at least partially overlapping the alignment hole in the plan view.

According to some embodiments, the hole area may be located between the third alignment pattern and the fourth alignment pattern.

According to some embodiments, the substrate may further include a second non-display area surrounding at least a portion of the display area and in which a driver is located.

According to some embodiments, the display device may further include an insulating pattern located in the first non-display area and spaced apart from the first dam in the plan view and a metal pattern covering at least a portion of the insulating pattern.

According to some embodiments, one end of the metal pattern and the insulating pattern may be spaced apart to form an undercut area.

According to some embodiments, the alignment hole and the metal pattern may be spaced apart from each other in the plan view.

According to some embodiments of the present disclosure, a display device includes pixels located in a display area, a component spaced apart from the pixels in a plan view, a dam surrounding at least a portion of the component, and a first alignment pattern at least partially overlapping the alignment hole in the plan view.

According to some embodiments, the dam may include an alignment hole.

According to some embodiments, the alignment hole may overlap one end of the first alignment pattern in the plan view.

According to some embodiments, the display device may further include a second alignment pattern spaced apart from the first alignment pattern and at least partially overlapping the alignment hole in the plan view.

According to some embodiments, the component may be located between the first alignment pattern and the second alignment pattern.

According to some embodiments of the present disclosure, an electronic device includes a substrate including a hole area, a first non-display area surrounding at least a portion of the hole area, and a display area surrounding at least a portion of the first non-display area, pixels located in the display area on the substrate, a first dam located in the first non-display area on the substrate, a first alignment pattern located in the first non-display area on the first dam, and a memory configured to store data information.

According to some embodiments, the first dam may include an alignment hole.

According to some embodiments, the first alignment pattern may at least partially overlap the alignment hole in a plan view.

According to some embodiments of the present disclosure, a display device includes a substrate including a hole area, a first non-display area surrounding at least a portion of the hole area, and a display area surrounding at least a portion of the first non-display area, pixels located in the display area on the substrate, a first dam located in the first non-display area on the substrate, and a first alignment pattern located in the first non-display area on the first dam. According to some embodiments, the first dam may include an alignment hole. According to some embodiments, the first alignment pattern may at least partially overlap the alignment hole in a plan view.

Accordingly, a recognition rate of the first alignment pattern may be relatively improved. Accordingly, it may be possible to relatively easily check whether the hole area is properly formed by using the first alignment pattern.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments.

FIG. 2 is a circuit diagram illustrating pixel in the display device of FIG. 1.

FIG. 3 is a cross-sectional view illustrating an example of the display device of FIG. 1 taken along the line I-I′.

FIG. 4 is a cross-sectional view illustrating an example of the display device of FIG. 1 taken along the line I-I′.

FIG. 5 is a plan view illustrating a partial area of the display device of FIG. 1.

FIG. 6 is a cross-sectional view of the display device of FIG. 5 taken along the line II-II′.

FIG. 7 is a plan view illustrating a partial area of the display device of FIG. 1.

FIG. 8 is an enlarged cross-sectional view of an area A of FIG. 6.

FIG. 9 is a block diagram illustrating an electronic device according to some embodiments.

FIG. 10 is a schematic diagram of an electronic device according to some embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

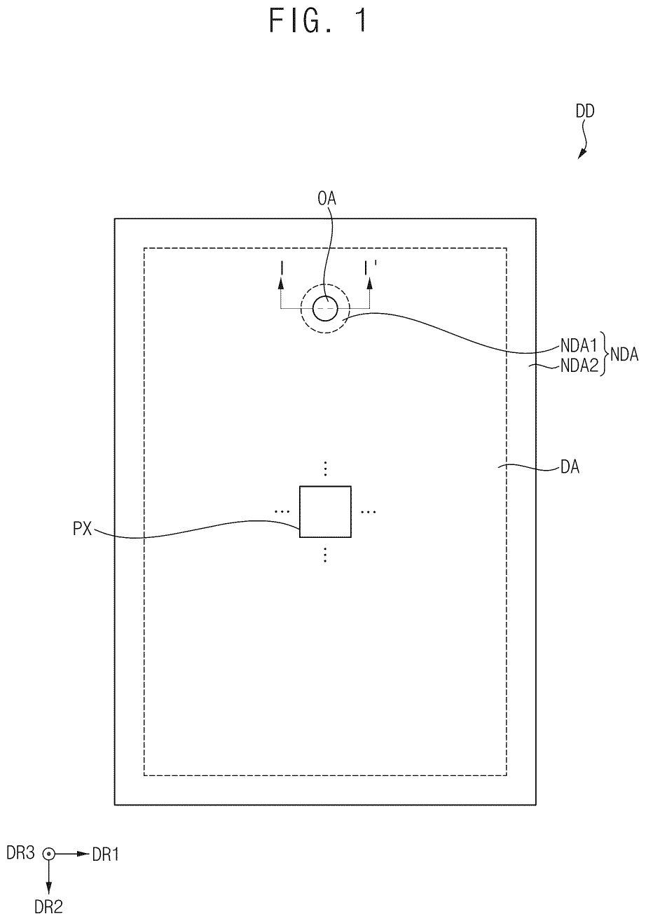

FIG. 1 is a plan view illustrating a display device according to some embodiments.

Referring to FIG. 1, a display device DD according to some embodiments may be a device activated by an electrical signal. For example, the display device DD may be a small display device used in small electronic devices such as smartphones, mobile phones, smart watches, game consoles, cameras, and/or the like. However, embodiments according to the present disclosure are not limited thereto, and the display device DD may be a medium to large-sized display device used in medium to large-sized display devices such as laptops, tablets, PCs, televisions, computer monitors, vehicle monitors, external billboards, and/or the like.

The display device DD may include a display area DA, a non-display area NDA, and a hole area OA.

The display area DA may be an area in which images are displayed. For example, the display area DA may be defined as an area capable of displaying images by generating light or adjusting transmittance of light provided from an external light source. Pixels PX may be located in the display area DA. Each of the pixels PX may emit light. The pixels PX may be spaced apart from each other in a plan view. The pixels PX may be overall located in the display area DA. As each of the pixels PX emits light in the display area DA, the display area DA may display images.

The non-display area NDA may be an area that does not display images. For example, the pixels PX may not be located in the non-display area NDA. According to some embodiments, the non-display area NDA may include a first non-display area NDA1 and a second non-display area NDA2.

The first non-display area NDA1 may be located in (e.g., surrounded by) the display area DA. For example, the display area DA may surround at least a portion of the first non-display area NDA1. According to some embodiments, the first non-display area NDA1 may be located at an upper center of the display area DA. However, embodiments according to the present disclosure are not limited thereto, and position of the first non-display area NDA1 may be variously changed according to embodiments. For example, the first non-display area NDA1 may be located at a left upper end of the display area DA or may be located at a right upper end.

The second non-display area NDA2 may surround at least a portion of the display area DA. For example, the second non-display area NDA2 may be in a periphery (or outside a footprint of) the display area DA. A driver may be located in the second non-display area NDA2. For example, the driver may include a data driver, a gate driver, and/or the like.

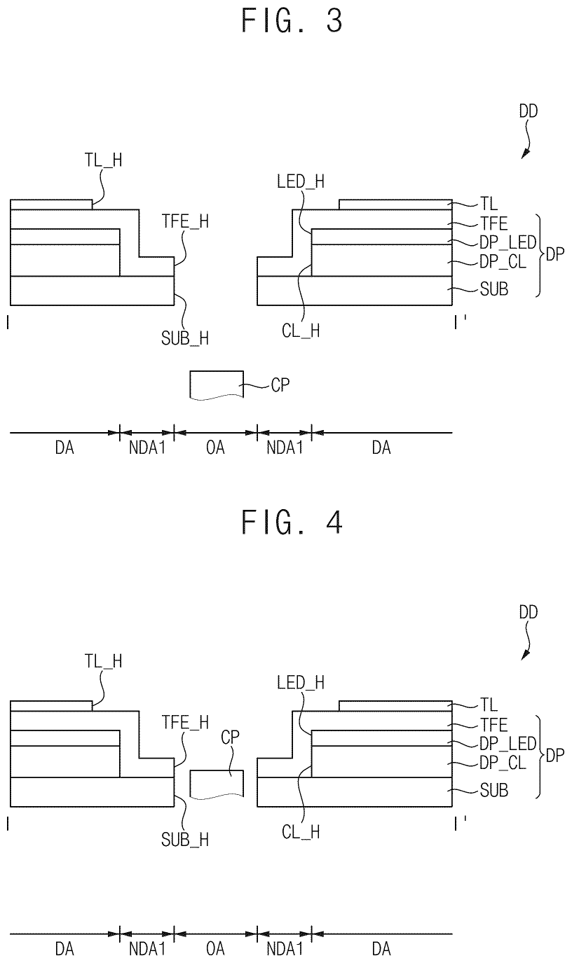

The hole area OA may be located in the first non-display area NDA1. For example, the first non-display area NDA1 may surround at least a portion of the hole area OA. As described above, the first non-display area NDA1 may be located at the upper center of the display area DA. Accordingly, the hole area OA located in the first non-display area NDA1 may also be located at the upper center of the display area DA. For example, position of the hole area OA may be changed according to position of the first non-display area NDA1. According to some embodiments, the hole area OA may have a circular shape in the plan view. However, embodiments according to the present disclosure are not limited thereto, and shape of the hole area OA in the plan view may be variously changed according to embodiments. For example, the hole area OA may have a polygonal shape in the plan view. A component (e.g., a component CP of FIG. 3) may be located in the hole area OA. Light, sound, and/or the like output from the component to an outside or traveling toward the component from the outside may pass through the hole area OA. The hole area OA may not display an image. For example, the pixels PX may not be located in the hole area OA.

According to some embodiments, the first direction DR1 and the second direction DR2 crossing the first direction DR1 may be defined. For example, the second direction DR2 may be substantially perpendicular to the first direction DR1. However, embodiments according to the present disclosure are not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially perpendicular to the plane formed by the first direction DR1 and the second directions DR2. However, embodiments according to the present disclosure are not limited thereto, and the third direction DR3 may form an acute angle or an obtuse angle with the plane formed by the first direction DR1 and the second direction DR2.

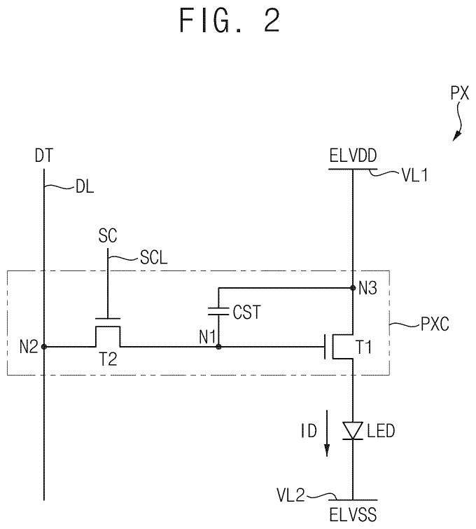

FIG. 2 is a circuit diagram illustrating aspects of a pixel in the display device of FIG. 1 according to some embodiments. Although various components are illustrated in the pixel in FIG. 2, embodiments according to the present disclosure are not limited thereto, and according to various embodiments, the pixel may include additional components without departing from the spirit and scope of embodiments according to the present disclosure.

Referring to FIG. 2, each of the pixels PX may include a light-emitting element LED and a pixel driving circuit portion PXC electrically connected to the light-emitting element LED. The pixel driving circuit portion PXC may include a first transistor T1, a second transistor T2, and a capacitor CST.

According to some embodiments, each of the first transistor T1 and the second transistor T2 may be an n-type transistor. An active pattern of the n-type transistor may include an oxide semiconductor material. However, embodiments according to the present disclosure are not limited thereto, and the active pattern of the n-type transistor may include a silicon semiconductor material. According to some embodiments, each of the first transistor T1 and the second transistor T2 may be a p-type transistor. An active pattern of the p-type transistor may include a silicon semiconductor material. According to some embodiments, some of the first transistor T1 and the second transistor T2 may be n-type transistors, and other may be p-type transistors.

The pixel driving circuit portion PXC may be electrically connected to a first voltage line VL1, a second voltage line VL2, a data line DL and a scan line SCL. The first voltage line VL1 may apply a first power voltage ELVDD to the pixel driving circuit portion PXC. The second voltage line VL2 may apply a second power voltage ELVSS to the pixel driving circuit portion PXC. According to some embodiments, a voltage level of the first power voltage ELVDD may be higher than a voltage level of the second power voltage ELVSS. The data line DL may apply a data voltage DT to the pixel driving circuit portion PXC. The scan line SCL may apply a scan signal SC to the pixel driving circuit portion PXC.

The first transistor T1 may include a gate terminal, a first terminal, and a second terminal. The gate terminal of the first transistor T1 may be connected to a first node N1. The first terminal of the first transistor T1 may be connected to a third node N3. For example, the first terminal of the first transistor T1 may be connected to the first voltage line VL1 through the third node N3. The second terminal of the first transistor T1 may be connected to a first terminal of the light-emitting element LED. The first transistor T1 may provide driving current ID to the light-emitting element LED. For example, the first transistor T1 may be a driving transistor.

The second transistor T2 may include a gate terminal, a first terminal, and a second terminal. The gate terminal of the second transistor T2 may be connected to the scan signal line SCL. The first terminal of the second transistor T2 may be connected to a second node N2. The second terminal of the second transistor T2 may be connected to the first node N1.

The gate terminal of the second transistor T2 may receive the scan signal SC through the scan signal line SCL. The second transistor T2 may be turned on or off in response to the scan signal SC. For example, when the second transistor T2 is an n-type transistor, the second transistor T2 may be turned off when the scan signal SC has a negative voltage level, and may be turned on when the scan signal SC has a positive voltage level. In addition, when the second transistor T2 is a p-type transistor, the second transistor T2 may be turned off when the scan signal SC has a positive voltage level, and may be turned on when the scan signal SC has a negative voltage level. The first terminal of the second transistor T2 may receive the data voltage DT through the data line DL. The second terminal of the second transistor T2 may provide the data voltage DT to the first node N1 during a period in which the second transistor T2 is turned on. Accordingly, the second transistor T2 may drive the first transistor T1.

The capacitor CST may include a first terminal and a second terminal. The first terminal of the capacitor CST may be connected to the third node N3. The second terminal of the capacitor CST may be connected to the first node N1. Electric charges corresponding to a difference between voltage of the gate terminal of the first transistor T1 and the first power voltage ELVDD may be stored in the capacitor CST.

The light-emitting element LED may include a first terminal and a second terminal. The first terminal of the light-emitting element LED may be connected to the second terminal of the first transistor T1. The second terminal of the light-emitting element LED may be connected to the second voltage line VL2. For example, the first terminal of the light-emitting element LED may be an anode terminal, and the second terminal of the light-emitting element LED may be a cathode terminal.

As illustrated in FIG. 2, the pixel driving circuit portion PXC may include two transistors and one capacitor. However, embodiments according to the present disclosure are not limited thereto, and number of transistors and capacitors included in the pixel driving circuit portion PXC may be variously changed according to embodiments.

FIG. 3 is a cross-sectional view illustrating an example of the display device of FIG. 1 taken along the line I-I′. FIG. 4 is a cross-sectional view illustrating an example of the display device of FIG. 1 taken along the line I-I′.

Referring to FIG. 3, the display device DD may include a display panel DP, an input sensing layer TL, and a component CP. The display panel DP may include a substrate SUB, a circuit layer DP_CL, an element layer DP_LED, and an encapsulation layer TFE.

The substrate SUB may be a base (e.g., a base layer or a bottom layer) of the display panel DP. The substrate SUB may define a first opening SUB_H. The first opening SUB_H may be formed corresponding to the hole area OA. The first opening SUB_H may penetrate from an upper surface of the substrate SUB to a lower surface of the substrate SUB to form an opening passing entirely therethrough.

The circuit layer DP_CL may be located on the substrate SUB. The circuit layer DP_CL may include a circuit element. For example, the circuit layer DP_CL may include the pixel driving circuit portion PXC of FIG. 2. The circuit layer DP_CL may define a second opening CL_H. The second opening CL_H may be formed corresponding to the hole area OA. According to some embodiments, a diameter of the second opening CL_H in a horizontal direction may be greater than a diameter of the first opening SUB_H in the horizontal direction, but embodiments according to the present disclosure are not limited thereto. The horizontal direction may be any direction parallel to a plane defined by the first direction DR1 and the second direction DR2.

The element layer DP_LED may be located on the circuit layer DP_CL. The element layer DP_LED may include the light-emitting element (for example, the light-emitting element LED of FIG. 2). The element layer DP_LED may define a third opening LED_H. The third opening LED_H may be formed corresponding to the hole area OA. According to some embodiments, a diameter of the third opening LED_H in the horizontal direction may be larger than the diameter of the first opening SUB_H in the horizontal direction, but embodiments according to the present disclosure are not limited thereto.

The encapsulation layer TFE may be located on the element layer DP_LED. The encapsulation layer TFE may prevent or reduce instances of contaminants or impurities such as moisture, oxygen, and/or the like penetrating into the element layer DP_LED. According to some embodiments, the encapsulation layer TFE may extend from an upper surface of the element layer DP_LED to cover a side surface of the element layer DP_LED. For example, the encapsulation layer TFE may extend to be located in the third opening LED_H. According to some embodiments, the encapsulation layer TFE may extend from the upper surface of the element layer DP_LED to cover the side surface of the element layer DP_LED and a side surface of the circuit layer DP_CL. For example, the encapsulation layer TFE may extend to be located in the third opening LED_H and the second opening CL_H. According to some embodiments, the encapsulation layer TFE may extend from the upper surface of the element layer DP_LED to cover the side surface of the element layer DP_LED, the side surface of the circuit layer DP_CL, and a portion of the upper surface of the substrate SUB. The encapsulation layer TFE may define a fourth opening TFE_H. The fourth opening TFE_H may be formed corresponding to the hole area OA. According to some embodiments, a diameter of the fourth opening TFE_H in the horizontal direction and the diameter of the first opening SUB_H in the horizontal direction may be substantially same. but embodiments according to the present disclosure are not limited thereto.

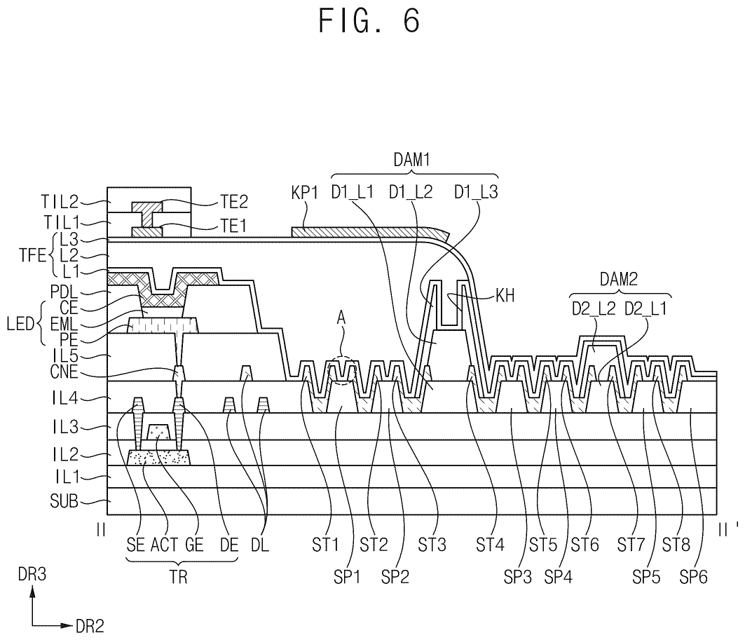

The input sensing layer TL may be located on the display panel DP. For example, the input sensing layer TL may be located on the encapsulation layer TFE. The input sensing layer TL may include an input electrode (e.g., a first input electrode TE1 and/or a second input electrode TE2 of FIG. 6) capable of sensing an external input. The external input may include contact by a portion of a body such as a user's hand or contact by an electronic pen such as a stylus pen. The input sensing layer TL may define a fifth opening TL_H. The fifth opening TL_H may be formed corresponding to the hole area OA. According to some embodiments, a diameter of the fifth opening TL_H in the horizontal direction may be greater than the diameter of the third opening LED_H in the horizontal direction, but embodiments according to the present disclosure are not limited thereto.

The component CP may be located in or at (e.g., overlapping in a plan view) the hole area OA. The component CP may include an electronic element. For example, the component CP may include an electronic element that uses light. For example, the electronic element may include an electronic element that uses infrared or visible light. For example, the electronic element may include a solar cell, a flash sensor, an illumination sensor, a proximity sensor, an iris sensor, and/or the like. For another example, the component CP may include an electronic element that uses sound. For example, the component CP may include a sensor, a speaker, and/or the like. that senses or outputs sound. The first opening SUB_H, the second opening CL_H, the third opening LED_H, the fourth opening TFE_H, and the fifth opening TL_H may communicate with each other to form a transmitting area through which light, sound, and/or the like output from the component CP to an outside or traveling from the outside toward the component CP may be transmitted.

According to some embodiments, as illustrated in FIG. 3, the component CP may be located under the substrate SUB. However, embodiments according to the present disclosure are not limited thereto, and position of the component CP may be variously changed in the hole area OA. For example, as illustrated in FIG. 4, the component CP may be located in the first opening SUB_H and the second opening CL_H. For example, the component CP may be located in the first opening SUB_H and the fourth opening TFE_H.

The hole area OA may be formed by a laser cutting process. For example, the first opening SUB_H, the second opening CP_H, the third opening LED_H, the fourth opening TFE_H and the fifth opening TL_H of FIG. 3 may be formed by the laser cutting process. However, embodiments according to the present disclosure are not limited thereto, and a method of forming the first opening SUB_H, the second opening CP_H, the third opening LED_H, the fourth opening TFE_H, and the fifth opening TL_H may be variously changed according to embodiments.

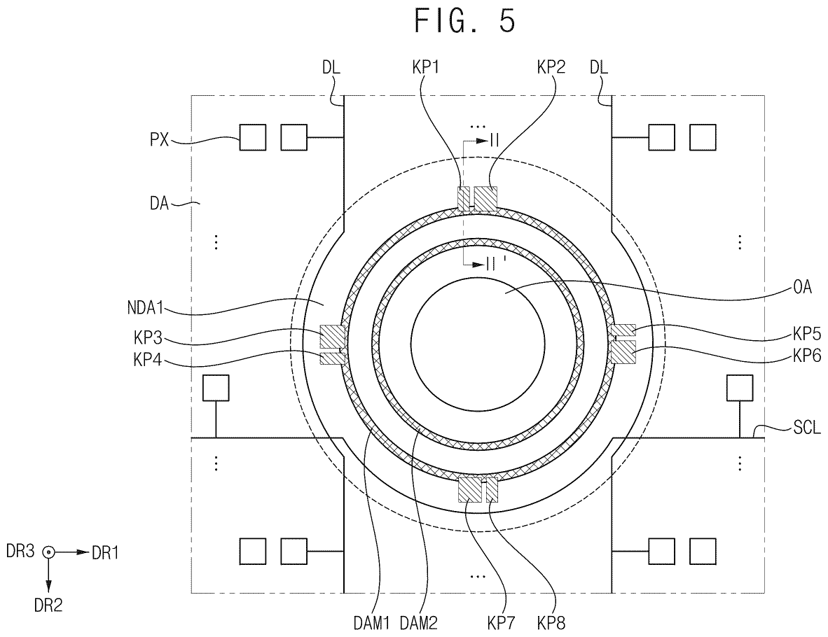

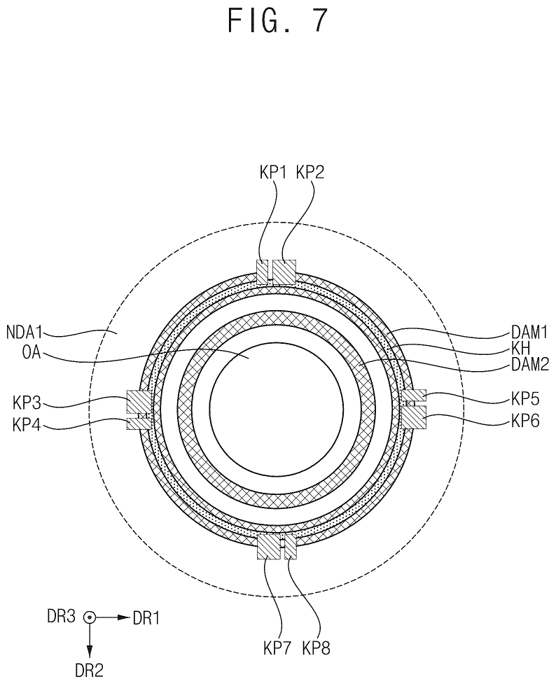

FIG. 5 is a plan view illustrating a partial area of the display device of FIG. 1. FIG. 6 is a cross-sectional view of the display device of FIG. 5 taken along the line II-II′. FIG. 7 is a plan view illustrating a partial area of the display device of FIG. 1. For example, FIG. 7 is an enlarged plan view of the first non-display area NDA1 and the hole area OA of FIG. 5.

Referring to FIG. 5, the display device (e.g., the display device DD of FIG. 1) may further include a first dam DAM1, a second dam DAM2, and alignment patterns. For example, the alignment patterns may include a first alignment pattern KP1, a second alignment pattern KP2, a third alignment pattern KP3, a fourth alignment pattern KP4, a fifth alignment pattern KP5, a sixth alignment pattern KP6, a seventh alignment pattern KP7, and an eighth alignment pattern KP8.

As described above, pixels PX may be located in the display area DA. The pixels PX may be spaced apart from the hole area OA in the plan view. For example, the pixels PX may be spaced apart from the component (e.g., the component CP of FIG. 3) located in the hole area OA in the plan view.

Each of the pixels PX may be connected to a corresponding data line DL of the data line DL. The data line DL may extend in the second direction DR2 in the display area DA, and may extend in an edge direction of the hole area OA in the first non-display area NDA1. For example, the data line DL may extend in the first non-display area NDA1 to bypass the hole area OA, the first dam DAM1, and the second dam DAM2.

The first dam DAM1 may be located in the first non-display area NDA1. According to some embodiments, the first dam DAM1 may surround at least a portion of the hole area OA. For example, the first dam DAM1 may have a ring shape that entirely surrounds the hole area OA. For example, the first dam DAM1 may have a ring shape that entirely surrounds the component located in the hole area OA. The first dam DMA1 may be located closer to the hole area OA than the data line DL and the scan signal line SCL. The first dam DAM1 may entirely surround the second dam DAM2.

The second dam DAM2 may be located in the first non-display area NDA1. The second dam DAM2 may be spaced apart from the first dam DAM1 in the plan view. The second dam DAM2 may surround at least a portion of the hole area OA. For example, the second dam DAM2 may have a ring shape that entirely surrounds the hole area OA. For example, the second dam DAM2 may have a ring shape that entirely surrounds the component located in the hole area OA. The second dam DAM2 may be located closer to the hole area OA than the first dam DAM1.

The alignment patterns may be located in the first non-display area NDA1. Each of the alignment patterns may at least partially overlap the first dam DAM1 in the plan view. For example, each of the first alignment pattern KP1, the second alignment pattern KP2, the third alignment pattern KP3, the fourth alignment pattern KP4, the fifth alignment pattern KP5, the sixth alignment pattern KP6, the seventh alignment pattern KP7, and the eighth alignment pattern KP8 may at least partially overlap the first dam DAM1 in the plan view.

The alignment patterns may be spaced apart from each other in the plan view. For example, the second alignment pattern KP2 may be spaced apart from the first alignment pattern KP1 in the first direction DR1. The fourth alignment pattern KP4 may be spaced apart from the third alignment pattern KP3 in the second direction DR2. The sixth alignment pattern KP6 may be spaced apart from the fifth alignment pattern KP5 in the second direction DR2. The eighth alignment pattern KP8 may be spaced apart from the seventh alignment pattern KP7 in the first direction DR1. The seventh alignment pattern KP7 may be spaced apart from the first alignment pattern KP1 in the plan view. The hole area OA (or the component) may be located between the seventh alignment pattern KP7 and the first alignment pattern KP1. For example, the first alignment pattern KP1 and the seventh alignment pattern KP7 may partially overlap each other in the second direction DR2. According to some embodiments, the seventh alignment pattern KP7 may also partially overlap the second alignment pattern KP2 in the second direction DR2. The eighth alignment pattern KP8 may be spaced apart from the second alignment pattern KP2 in the plan view. The hole area OA (or the component) may be located between the eighth alignment pattern KP8 and the second alignment pattern KP2. For example, the second alignment pattern KP2 and the eighth alignment pattern KP8 may partially overlap each other in the second direction DR2. According to some embodiments, the eighth alignment pattern KP8 may also partially overlap the first alignment pattern KP1 in the second direction DR2. The fifth alignment pattern KP5 may be spaced apart from the third alignment pattern KP3 in the plan view. The hole area OA (or the component) may be located between the fifth alignment pattern KP5 and the third alignment pattern KP3. For example, the third alignment pattern KP3 and the fifth alignment pattern KP5 may partially overlap each other in the first direction DR1. According to some embodiments, the fifth alignment pattern KP5 may also partially overlap the fourth alignment pattern KP4 in the first direction DR1. The sixth alignment pattern KP6 may be spaced apart from the fourth alignment pattern KP4. The hole area OA (or the component) may be located between the sixth alignment pattern KP6 and the fourth alignment pattern KP4. For example, the fourth alignment pattern KP4 and the sixth alignment pattern KP6 may partially overlap each other in the first direction DR1. According to some embodiments, the sixth alignment pattern KP6 may also partially overlap the third alignment pattern KP3 in the first direction DR1. According to some embodiments, as illustrated in FIG. 5, the alignment patterns may include eight alignment patterns. However, embodiments according to the present disclosure are not limited thereto, and number of the alignment patterns may be variously changed according to embodiments.

According to some embodiments, widths of adjacent alignment patterns of the alignment patterns may be different from each other. For example, a width of the second alignment pattern KP2 in the first direction DR1 may be greater than a width of the first alignment pattern KP1 in the first direction DR1. In addition, a width of the seventh alignment pattern KP7 in the first direction DR1 may be greater than a width of the eighth alignment pattern KP8 in the first direction DR1. In addition, a width of the third alignment pattern KP3 in the second direction DR2 may be greater than a width of the fourth alignment pattern KP4 in the second direction DR2. In addition, a width of the sixth alignment pattern KP6 in the second direction DR2 may be greater than a width of the fifth alignment pattern KP5 in the second direction DR2.

Through the alignment patterns, whether the hole area OA is properly formed may be confirmed. For example, by checking relative positions of the alignment patterns and the hole area OA, an area occupied by the hole area OA in the plan view and position of the hole area OA in the plan view may be confirmed. For example, by checking the relative positions of the alignment patterns and the hole area OA, whether the hole area OA is formed with being biased in the first direction DR1, in a direction opposite to the first direction DR1, a second direction, a direction opposite to the second direction DR2, and/or the like may be confirmed.

Referring further to FIG. 6, the substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other.

A first insulating layer IL1 may be located on the substrate SUB. The first insulating layer IL1 may prevent or reduce contaminants or impurities penetrating into an upper portion of the substrate SUB from an outside. For example, the first insulating layer IL1 may include an inorganic material such as silicon oxide, silicon nitride, silicon oxynitride, silicon oxycarbide, and/or the like. These materials may be used alone or in combination with each other.

An active pattern ACT may be located on the first insulating layer IL1. The active pattern ACT may include a first contact area, a second contact area, and a channel area located between the first contact area and the second contact area. For example, the active layer ACT may include an inorganic semiconductor (e.g., amorphous silicon, polysilicon, a metal oxide semiconductor), an organic semiconductor, and/or the like. These materials may be used alone or in combination with each other. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“T”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

A second insulating layer IL2 may be located on the first insulating layer IL1. The second insulating layer IL2 may cover the active pattern ACT. For example, the second insulating layer IL2 may include an inorganic material such as silicon oxide, silicon nitride, silicon oxynitride, or silicon oxycarbide. These materials may be used alone or in combination with each other.

A gate electrode GE may be located on the second insulating layer IL2. The gate electrode GE may overlap the channel area of the active pattern ACT in the plan view. The gate electrode GE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A third insulating layer IL3 may be located on the second insulating layer IL2. The third insulating layer IL3 may cover the gate electrode GE. For example, the third insulating layer IL3 may include an inorganic material such as silicon oxide, silicon nitride, silicon oxynitride, or silicon oxycarbide. These materials may be used alone or in combination with each other.

A first contact electrode SE and a second contact electrode DE may be located on the third insulating layer IL3. The first contact electrode SE may contact the first contact area of the active pattern ACT through a contact hole penetrating (or, defining in) the second insulating layer IL2 and the third insulating layer IL3. In addition, the second contact electrode DE may contact the second contact area of the active pattern ACT through a contact hole penetrating (or, defining in) the second insulating layer IL2 and the third insulating layer IL3. For example, each of the first contact electrode SE and the second contact electrode DE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A transistor TR may include the first contact electrode SE, the gate electrode GE, the active pattern ACT, and the second contact electrode DE. The transistor TR may be located in the display area DA. The transistor TR may correspond to the first transistor T1 of FIG. 2, but embodiments according to the present disclosure are not limited thereto.

A fourth insulating layer IL4 may be located on the third insulating layer IL3. The fourth insulating layer IL4 may cover the first contact electrode SE and the second contact electrode DE. For example, the fourth insulating layer IL4 may include an inorganic material such as silicon oxide, silicon nitride, silicon oxynitride, silicon oxycarbide, and/or the like. These materials may be used alone or in combination with each other. For another example, the fourth insulating layer IL4 may include an organic material such as a phenol resin, an acrylic resin, a polyimide resin, a polyamide resin, a siloxane resin, an epoxy resin, and/or the like. These materials may be used alone or in combination with each other.

A connection electrode CNE may be located on the fourth insulating layer IL4. The transistor TR and the pixel electrode PE may be connected to each other through the connection electrode CNE. For example, the connection electrode CNE may be connected to the second contact electrode DE through a contact hole penetrating (or, defining in) the fourth insulating layer IL4, and the pixel electrode PE may be connected to the connection electrode CNE through a contact hole penetrating (or, defining in) the fifth insulating layer IL5. For example, the connection electrode CNE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A fifth insulating layer IL5 may be located on the fourth insulating layer IL4. The fifth insulating layer IL5 may cover the connection electrode CNE. For example, the fifth insulating layer IL5 may include an organic material such as a phenol resin, an acrylic resin, a polyimide resin, a polyamide resin, a siloxane resin, an epoxy resin, and/or the like. These materials may be used alone or in combination with each other. For another example, the fifth insulating layer IL5 may include an inorganic material such as silicon oxide, silicon nitride, silicon oxynitride, silicon oxycarbide, and/or the like. These materials may be used alone or in combination with each other.

A pixel electrode PE may be located on the fifth insulating layer IL5. As described above, the pixel electrode PE may be connected to the connection electrode CNE through the contact hole penetrating (or, defining in) the fifth insulating layer IL5. For example, the pixel electrode PE may include a metal, an alloy, a metal nitride, a conductive metal oxide, a transparent conductive material, and/or the like. These materials may be used alone or in combination with each other. According to some embodiments, the pixel electrode PE may have a stacked structure including ITO/Ag/ITO. For example, the pixel electrode PE may operate as an anode of the light-emitting element LED. The pixel electrode PE may be referred to as a first electrode.

A pixel defining layer PDL may be located on the fifth insulating layer IL5. The pixel defining layer PDL may cover a side portion of the pixel electrode PE. For example, a pixel opening exposing a portion of an upper surface of the pixel electrode PE may be defined in the pixel defining layer PDL. According to some embodiments, the pixel defining layer PDL may include an organic material such as an epoxy resin, a siloxane resin, and/or the like. These materials may be used alone or in combination with each other. According to some embodiments, the pixel defining layer PDL may further include a black light blocking material. For example, the pixel defining layer PDL may further include a light blocking material including a black pigment, a black dye, and/or the like.

A light-emitting layer EML may be located on the pixel electrode PE. The light-emitting layer EML may at least partially overlap the pixel electrode PE in the plan view. For example, the light-emitting layer EML may be located in the pixel opening of the pixel defining layer PDL. For example, the light-emitting layer EML may include an organic material that emits selected light.

A common electrode CE may be located on the light-emitting layer EML and the pixel defining layer PDL. The common electrode CE may at least partially overlap the light-emitting layer EML in the plan view. For example, the common electrode CE may be located in the pixel opening of the pixel defining layer PDL. For example, the common electrode CE may include a metal, an alloy, a metal nitride, a conductive metal oxide, a transparent conductive material, and/or the like. These materials may be used alone or in combination with each other. The common electrode CE may operate as a cathode of the light-emitting element LED. The common electrode CE may be referred to as a second electrode.

A light-emitting element LED may include the pixel electrode PE, the light-emitting layer EML, and the common electrode CE. The light-emitting element LED may be located in the display area DA. The light-emitting element LED may correspond to the light-emitting element LED of FIG. 2.

The encapsulation layer TFE may be located on the light-emitting element LED. The encapsulation layer TFE may prevent or reduce contaminants or impurities such as moisture, oxygen, and/or the like penetrating into the light-emitting element LED. Specific structure of the encapsulation layer TFE will be described later.

As described above, the input sensing layer (for example, the input sensing layer TL of FIG. 3) may be located on the encapsulation layer TFE. The input sensing layer may include at least one input electrode and at least one input insulating layer. For example, as illustrated in FIG. 6, the input sensing layer may include a first input electrode TE1, a second input electrode TE2, a first input insulating layer TIL1, and a second input insulating layer TIL2. According to some embodiments, the input sensing layer may be located in the display area DA. According to some embodiments, the input sensing layer may extend to a portion of the first non-display area NDA1.

The first input electrode TE1 may be located on the encapsulation layer TFE. The first input electrode TE1 may have a single layer structure or a multilayer structure stacked along the third direction DR3. The first input electrode TE1 may include conductive patterns of a mesh shape, but embodiments according to the present disclosure are not limited thereto. For example, the first input electrode TE1 may include a metal, an alloy, a metal nitride, a conductive metal oxide, a transparent conductive material, and/or the like. These materials may be used alone or in combination with each other.

The first input insulating layer TIL1 may be located on the encapsulation layer TFE. The first input insulating layer TIL1 may cover the first input electrode TE1. For example, the first input insulating layer TIL1 may include an inorganic material such as silicon oxide, silicon nitride, silicon oxynitride, or silicon oxycarbide. These materials may be used alone or in combination with each other.

The second input electrode TE2 may be located on the first input insulating layer TIL1. The second input electrode TE2 may have a single layer structure or a multilayer structure stacked along the third direction DR3. The second input electrode TE2 may include conductive patterns of a mesh shape, but embodiments according to the present disclosure are not limited thereto. According to some embodiments, the second input electrode TE2 may be connected to the first input electrode TE1 through a contact hole penetrating (or, defining in) the first input insulating layer TIL1. For example, some of the conductive patterns included in the second input electrode TE2 and some of the conductive patterns included in the first input electrode TE1 may be connected through a contact hole penetrating (or, defining in) the first input insulating layer TIL1. For example, the second input electrode TE2 may include a metal, an alloy, a metal nitride, a conductive metal oxide, a transparent conductive material, and/or the like. These materials may be used alone or in combination with each other.

The second input insulating layer TIL2 may be located on the first input insulating layer TIL1. The second input insulating layer TIL2 may cover the second input electrode TE2. For example, the second input insulating layer TIL2 may include an inorganic material such as silicon oxide, silicon nitride, silicon oxynitride, silicon oxycarbide, and/or the like. These materials may be used alone or in combination with each other.

Components located in the first non-display area NDA1 will be further described below.

The data line DL, insulating patterns, metal patterns, the first dam DAM1, the second dam DAM2, and the first alignment pattern KP1 may be located in the first non-display area NDA1. The insulating patterns may include a first insulating pattern SP1, a second insulating pattern SP2, a third insulating pattern SP3, a fourth insulating pattern SP4, a fifth insulating pattern SP5, and a sixth insulating pattern SP6. The metal patterns may include a first metal pattern ST1, a second metal pattern ST2, a third metal pattern ST3, a fourth metal pattern ST4, a fifth metal pattern ST5, a sixth metal pattern ST6, a seventh metal pattern ST7, and an eighth metal pattern ST8.

According to some embodiments, the data line DL may be a data line DL extending to bypass the hole area OA described with reference to FIG. 5. According to some embodiments, the data line DL may be alternately located, with an insulating layer located between the data lines DL. For example, as illustrated in FIG. 6, a portion of the data line DL may be located on the third insulating layer IL3, and another portion of the third insulating layer IL3 may be located on the fourth insulating layer IL4. In this case, the portion of the data lines DL may include substantially a same material as the first contact electrode SE and the second contact electrode DE, and may be formed through a same process as the first contact electrode SE and the second contact electrode DE. In addition, the another portion of the data line DL may include substantially a same material as the connection electrode CNE, and may be formed through a same process as the connection electrode CNE. However, embodiments according to the present disclosure are not limited thereto, and according to some embodiments, all of the data lines DL may be located in a same layer. For example, all of the data lines DL may be located on the third insulating layer IL3, or all of the data lines DL may be located on the fourth insulating layer IL4.

The first insulating pattern SP1, the second insulating pattern SP2, the third insulating pattern SP3, the fourth insulating pattern SP4, the fifth insulating pattern SP5, and the sixth insulating pattern SP6 may be located on the third insulating layer IL3.

The first insulating pattern SP1 may be spaced apart from the fourth insulating layer IL4 in the plan view. According to some embodiments, the first insulating pattern SP1 may have a ring shape that entirely surrounds the hole area OA. For example, according to some embodiments, the first insulating pattern SP1 may have a ring shape that entirely surrounds the hole area OA like the first dam DAM1.

The second insulating pattern SP2 may be spaced apart from the first insulating pattern SP1 in the plan view. According to some embodiments, the second insulating pattern SP2 may have a ring shape that entirely surrounds the hole area OA. For example, according to some embodiments, the second insulating pattern SP2 may have a ring shape that entirely surrounds the hole area OA like the first dam DAM1. The second insulating pattern SP2 may be located closer to the hole area OA than the first insulating pattern SP1.

The third insulating pattern SP3 may be spaced apart from the second insulating pattern SP2 in the plan view. According to some embodiments, the third insulating pattern SP3 may have a ring shape that entirely surrounds the hole area OA. For example, according to some embodiments, the third insulating pattern SP3 may have a ring shape that entirely surrounds the hole area OA like the first dam DAM1. The third insulating pattern SP3 may be located closer to the hole area OA than the second insulating pattern SP2.

The fourth insulating pattern SP4 may be spaced apart from the third insulating pattern SP3 in the plan view. According to some embodiments, the fourth insulating pattern SP4 may have a ring shape that entirely surrounds the hole area OA. For example, according to some embodiments, the fourth insulating pattern SP4 may have a ring shape that entirely surrounds the hole area OA like the first dam DAM1. The fourth insulating pattern SP4 may be located closer to the hole area OA than the third insulating pattern SP3.

The fifth insulating pattern SP5 may be spaced apart from the fourth insulating pattern SP4 in the plan view. According to some embodiments, the fifth insulating pattern SP5 may have a ring shape that entirely surrounds the hole area OA. For example, according to some embodiments, the fifth insulating pattern SP5 may have a ring shape that entirely surrounds the hole area OA like the first dam DAM1. The fifth insulating pattern SP5 may be located closer to the hole area OA than the fourth insulating pattern SP4.

The sixth insulating pattern SP6 may be spaced apart from the fifth insulating pattern SP5 in the plan view. According to some embodiments, the sixth insulating pattern SP6 may have a ring shape that entirely surrounds the hole area OA. For example, according to some embodiments, the sixth insulating pattern SP6 may have a ring shape that entirely surrounds the hole area OA like the first dam DAM1. The sixth insulating pattern SP6 may be located closer to the hole area OA than the fifth insulating pattern SP5.

According to some embodiments, the first insulating pattern SP1, the second insulating pattern SP2, the third insulating pattern SP3, the fourth insulating pattern SP4, the fifth insulating pattern SP5, and the sixth insulating pattern SP6 may include substantially a same material as the fourth insulating layer IL4. For example, a preliminary insulating layer may be formed on the third insulating layer IL3, and a portion of the preliminary insulating layer may be removed to form the fourth insulating layer IL4, the first insulating pattern SP1, the second insulating pattern SP2, the third insulating pattern SP3, the fourth insulating pattern SP4, the fifth insulating pattern SP5, and the sixth insulating pattern SP6, but embodiments according to the present disclosure are not limited thereto. The fourth insulating layer IL4, the first insulating pattern SP1, the second insulating pattern SP2, the third insulating pattern SP3, the fourth insulating pattern SP4, the fifth insulating pattern SP5, and the sixth insulating pattern SP6 may be located in substantially a same layer.

According to some embodiments, as illustrated in FIG. 6, the insulating patterns may include six insulating patterns, but embodiments according to the present disclosure are not limited thereto, and number of the insulating patterns may be variously changed according to embodiments.

The first metal pattern ST1, the second metal pattern ST2, the third metal pattern ST3, the fourth metal pattern ST4, the fifth metal pattern ST5, the sixth metal pattern ST6, the seventh metal pattern ST7, and the eighth metal pattern ST8 may be located on the third insulating layer IL3.

The first metal pattern ST1 may cover a portion of the fourth insulating layer IL4 and a portion of the first insulating pattern SP1. According to some embodiments, the first metal pattern ST1 may have a ring shape that entirely surrounds the hole area OA. For example, according to some embodiments, the first metal pattern ST1 may have a ring shape that entirely surrounds the hole area OA like the first dam DAM1.

The second metal pattern ST2 may cover a portion of the first insulating pattern SP1 and a portion of the second insulating pattern SP2. The second metal pattern ST2 may be spaced apart from the first metal pattern ST1 in the plan view. According to some embodiments, the second metal pattern ST2 may have a ring shape that entirely surrounds the hole area OA. For example, according to some embodiments, the second metal pattern ST2 may have a ring shape that entirely surrounds the hole area OA like the first dam DAM1. The second metal pattern ST2 may be located closer to the hole area OA than the first metal pattern ST1.

The third metal pattern ST3 may cover a portion of the second insulating pattern SP2 and a portion of a first layer D1_L1 of the first dam DAM1 to be described later. The third metal pattern ST3 may be spaced apart from the second metal pattern ST2 in the plan view. According to some embodiments, the third metal pattern ST3 may have a ring shape that entirely surrounds the hole area OA. For example, according to some embodiments, the third metal pattern ST3 may have a ring shape that entirely surrounds the hole area OA like the first dam DAM1. The third metal pattern ST3 may be located closer to the hole area OA than the second metal pattern ST2.

The fourth metal pattern ST4 may cover a portion of the first layer D1_L1 of the first dam DAM1 and a portion of the third insulating pattern SP3. The fourth metal pattern ST4 may be spaced apart from the third metal pattern ST3 in the plan view. According to some embodiments, the fourth metal pattern ST4 may have a ring shape that entirely surrounds the hole area OA. For example, according to some embodiments, the fourth metal pattern ST4 may have a ring shape that entirely surrounds the hole area OA like the first dam DAM1. The fourth metal pattern ST4 may be located closer to the hole area OA than the third metal pattern ST3.

The fifth metal pattern ST5 may cover a portion of the third insulating pattern SP3 and a portion of the fourth insulating pattern SP4. The fifth metal pattern ST5 may be spaced apart from the fourth metal pattern ST4 in the plan view. According to some embodiments, the fifth metal pattern ST5 may have a ring shape that entirely surrounds the hole area OA. For example, according to some embodiments, the fifth metal pattern ST5 may have a ring shape that entirely surrounds the hole area OA like the first dam DAM1. The fifth metal pattern ST5 may be located closer to the hole area OA than the fourth metal pattern ST4.

The sixth metal pattern ST6 may cover a portion of the fourth insulating pattern SP4 and a portion of a first layer D2_L1 of the second dam DAM2 to be described later. The sixth metal pattern ST6 may be spaced apart from the fifth metal pattern ST5 in the plan view. According to some embodiments, the sixth metal pattern ST6 may have a ring shape that entirely surrounds the hole area OA. For example, according to some embodiments, the sixth metal pattern ST6 may have a ring shape that entirely surrounds the hole area OA like the first dam DAM1. The sixth metal pattern ST6 may be located closer to the hole area OA than the fifth metal pattern ST5.

The seventh metal pattern ST7 may cover a portion of the first layer D2_L1 of the second dam DAM2 and a portion of the fifth insulating pattern SP5. The seventh metal pattern ST7 may be spaced apart from the sixth metal pattern ST6 in the plan view. According to some embodiments, the seventh metal pattern ST7 may have a ring shape that entirely surrounds the hole area OA. For example, according to some embodiments, the seventh metal pattern ST7 may have a ring shape that entirely surrounds the hole area OA like the first dam DAM1. The seventh metal pattern ST7 may be located closer to the hole area OA than the sixth metal pattern ST6.

The eighth metal pattern ST8 may cover a portion of the fifth insulating pattern SP5 and a portion of the sixth insulating pattern SP6. The eighth metal pattern ST8 may be spaced apart from the seventh metal pattern ST7 in the plan view. According to some embodiments, the eighth metal pattern ST8 may have a ring shape that entirely surrounds the hole area OA. For example, according to some embodiments the eighth metal pattern ST8 may have a ring shape that entirely surrounds the hole area OA like the first dam DAM1. The eighth metal pattern ST8 may be located closer to the hole area OA than the seventh metal pattern ST7.

According to some embodiments, the first metal pattern ST1, the second metal pattern ST2, the third metal pattern ST3, the fourth metal pattern ST4, the fifth metal pattern ST5, the sixth metal pattern ST6, the seventh metal pattern ST7, and the eighth metal pattern ST8 may include substantially a same material as the connection electrode CNE, but embodiments according to the present disclosure are not limited thereto.

According to some embodiments, as illustrated in FIG. 6, the metal patterns may include eight metal patterns, but embodiments according to the present disclosure are not limited thereto, and number of the metal patterns may be variously changed according to embodiments.

The first dam DAM1 may be located between the second insulating pattern SP2 and the third insulating pattern SP3 in the plan view. The first dam DAM1 may be located on the third insulating layer IL3. When the encapsulation layer TFE is formed, the first dam DAM1 may prevent or reduce overflowing of the encapsulation layer TFE into the hole area OA. For example, the first dam DAM1 may prevent or reduce overflowing of an organic encapsulation layer L2, which will be described in more detail later, into the hole area OA. For example, the first dam DAM1 may prevent or reduce overflowing of the organic encapsulation layer L2 into the component.

According to some embodiments, the first dam DAM1 may include a first layer D1_L1, a second layer D1_L2, and a third layer D1_L3.

The first layer D1_L1 may be located on the third insulating layer IL3. The first layer D1_L1 may have a ring shape that entirely surrounds the hole area OA. The first layer D1_L1 and the fourth insulating layer IL4 may include substantially a same material. For example, a preliminary insulating layer is formed on the third insulating layer IL3, and a portion of the preliminary insulating layer is removed to form the fourth insulating layer IL4, the first insulating pattern SP1, the second insulating pattern SP2, the third insulating pattern SP3, the fourth insulating pattern SP4, the fifth insulating pattern SP5, the sixth insulating pattern SP6, and the first layer D1_L1, but embodiments according to the present disclosure are not limited thereto. The fourth insulating layer IL4, the first insulating pattern SP1, the second insulating pattern SP2, the third insulating pattern SP3, the fourth insulating pattern SP4, the fifth insulating pattern SP5, the sixth insulating pattern SP6, and the first layer D1_L1 may be located in substantially a same layer.

The second layer D1_L2 may be located on the first layer D1_L1. The second layer D1_L2 may have a ring shape that entirely surrounds the hole area OA. The second layer D1_L2 and the fifth insulating layer IL5 may include substantially a same material. The second layer D1_L2 and the fifth insulating layer IL5 may be located in substantially a same layer. The second layer D1_L2 may cover a portion of the third metal pattern ST3 and a portion of the fourth metal pattern ST4.

The third layer D1_L3 may be located on the second layer D1_L2. The third layer D1_L3 may have a ring shape that entirely surrounds the hole area OA. The third layer D1_L3 and the pixel defining layer PDL may include substantially a same material. The third layer D1_L3 and the pixel defining layer PDL may be located in substantially a same layer.

The second dam DAM2 may be located between the fourth insulating pattern SP4 and the fifth insulating pattern SP5 in the plan view. The second dam DAM2 may be located on the third insulating layer IL3. The second dam DAM2 may prevent or reduce overflowing of the encapsulation layer TFE into the hole area OA when forming the encapsulation layer TFE like the first dam DAM1. For example, the second dam DAM2 may prevent or reduce overflowing of the organic encapsulation layer L2 into the hole area OA. For example, the second dam DAM2 may prevent or reduce overflowing of the organic encapsulation layer L2 into the component. For example, the second dam DAM2 may block the organic encapsulation layer L2 that the first dam DAM1 does not prevent or reduce overflowing into the hole area OA.

According to some embodiments, the second dam DAM2 may include a first layer D2_L1 and a second layer D2_L2.

The first layer D2_L1 may be located on the third insulating layer IL3. The first layer D2_L1 may have a ring shape that entirely surrounds the hole area OA. The first layer D2_L1 and the fourth insulating layer IL4 may include substantially a same material. For example, a preliminary insulating layer is formed on the third insulating layer IL3, and a portion of the preliminary insulating layer is removed to form the fourth insulating layer IL4, the first insulating pattern SP1, the second insulating pattern SP2, the third insulating pattern SP3, the fourth insulating pattern SP4, the fifth insulating pattern SP5, the sixth insulating pattern SP6, the first layer D1_L1, and the first layer D2_L1, but embodiments according to the present disclosure are not limited thereto. The fourth insulating layer IL4, the first insulating pattern SP1, the second insulating pattern SP2, the third insulating pattern SP3, the fourth insulating pattern SP4, the fifth insulating pattern SP5, the sixth insulating pattern SP6, the first layer D1_L1, and the first layer D2_L1 may be located in substantially a same layer.

The second layer D2_L2 may be located on the first layer D2_L1. The second layer D2_L2 may have a ring shape that entirely surrounds the hole area OA. The second layer D2_L2 and the pixel defining layer PDL may include substantially a same material. The second layer D2_L2 may cover a portion of the sixth metal pattern ST6 and a portion of the seventh metal pattern ST7.

As illustrated in FIG. 6, the second dam DAM2 may include a first layer D2_L1 and a second layer D2_L2, but embodiments according to the present disclosure are not limited thereto, and the second dam DAM2 may include three or more layers. For example, the second dam DAM2 may include a first layer D2_L1, a second layer D2_L2, and a third layer. In this case, the second layer D2_L2 and the fifth insulating layer IL5 may include substantially a same material, and the third layer and the pixel defining layer PDL may include substantially a same material.

As illustrated in FIG. 6, two dams (i.e., the first dam DAM1 and the second dam DAM2) may be located in the first non-display area NDA1. However, embodiments according to the present disclosure are not limited thereto, and three or more dams may be located in the first non-display area NDA1. As number of dams located in the first non-display area NDA1 increases, a probability that the encapsulation layer TFE overflows into the hole area OA may decrease.

The encapsulation layer TFE may include a first inorganic encapsulation layer L1, an organic encapsulation layer L2, and a second inorganic encapsulation layer L3. The first inorganic encapsulation layer L1 may cover at least a portion of each of the common electrode CE, the pixel defining layer PDL, the fifth insulating layer IL5, the fourth insulating layer IL4, the insulating patterns, the metal patterns, the first dam DAM1 and the second dam DAM2. For example, the first inorganic encapsulation layer L1 may include an inorganic material such as silicon oxide, silicon nitride, silicon oxynitride, silicon oxycarbide, and/or the like. These materials may be used alone or in combination with each other. The organic encapsulation layer L2 may be located on the first inorganic encapsulation layer L1. As described above, the organic encapsulation layer L2 may not overflow into the hole area OA by the first dam DAM1 and the second dam DAM2. For example, as illustrated in FIG. 6, the organic encapsulation layer L2 may be formed up to an upper portion of the first dam DAM1. For example, the organic encapsulation layer L2 may include an organic material such as phenol resin, acrylic resin, polyimide resin, polyamide resin, siloxane resin, epoxy resin, and/or the like. These materials may be used alone or in combination with each other. The second inorganic encapsulation layer L3 may be located on the organic encapsulation layer L2. The second inorganic encapsulation layer L3 may cover the organic encapsulation layer L2 in an area where the organic encapsulation layer L2 is formed, and may cover the first inorganic encapsulation layer L1 in an area where the organic encapsulation layer L2 is not formed. For example, the second inorganic encapsulation layer L3 may include an inorganic material such as silicon oxide, silicon nitride, silicon oxynitride, silicon oxycarbide, and/or the like. These materials may be used alone or in combination with each other.

The first alignment pattern KP1 may be located on the second inorganic encapsulation layer L3. For example, the first alignment pattern KP1 may cover a portion of the second inorganic encapsulation layer L3. According to some embodiments, the first alignment pattern KP1 and the first input electrode TE1 may include substantially a same material. According to some embodiments, the first alignment pattern KP1 and the first input electrode TE1 may be located in substantially a same layer. Although only the first alignment pattern KP1 is illustrated in FIG. 6, embodiments according to the present disclosure are not limited thereto, and each of the second alignment pattern KP2, the third alignment pattern KP3, the fourth alignment pattern KP4, the fifth alignment pattern KP5, the sixth alignment pattern KP6, the seventh alignment pattern KP7, and the eighth alignment pattern KP8 may include substantially a same material as the first input electrode TE1, and may be located in substantially a same layer as the first input electrode TE1.

Referring further to FIG. 7, according to some embodiments, the first dam DAM1 may include an alignment hole KH. For example, the third layer D1_L3 may define the alignment hole KH. According to some embodiments, the alignment hole KH may be a portion removed from an upper surface to a lower surface of the third layer D1_L3. For example, the alignment hole KH may penetrate from an upper surface to a lower surface of the third layer D1_L3. However, embodiments according to the present disclosure are not limited thereto, and according to some embodiments, the alignment hole KH may be a portion obtained by removing only a portion of the third layer D1_L3 from an upper surface of the third layer D1_L3. For example, the alignment hole KH may penetrate only a portion of the third layer D1_L3 from an upper surface of the third layer D1_L3.

As illustrated in FIG. 7, the alignment hole KH may have a ring shape surrounding the hole area OA. For example, the alignment hole KH may have a ring shape surrounding the hole area OA in the plan view in an area in which the first dam DAM1 is formed.

According to some embodiments, each of the alignment patterns may at least partially overlap the alignment hole KH in the plan view. For example, each of the first alignment pattern KP1, the second alignment pattern KP2, the third alignment pattern KP3, the fourth alignment pattern KP4, the fifth alignment pattern KP5, the sixth alignment pattern KP6, the seventh alignment pattern KP7, and the eighth alignment pattern KP8 may at least partially overlap the alignment hole KH in the plan view. For example, as illustrated in FIG. 7, one end of each of the alignment patterns may overlap the alignment hole KH in the plan view. For example, one end of each of the first alignment pattern KP1, the second alignment pattern KP2, the third alignment pattern KP3, the fourth alignment pattern KP4, the fifth alignment pattern KP5, the sixth alignment pattern KP6, the seventh alignment pattern KP7, and the eighth alignment pattern KP8 may overlap the alignment hole KH in the plan view. The one end of each of the first alignment pattern KP1, the second alignment pattern KP2, the third alignment pattern KP3, the fourth alignment pattern KP4, the fifth alignment pattern KP5, the sixth alignment pattern KP6, the seventh alignment pattern KP7, and the eighth alignment pattern KP8 may be a portion facing the hole area OA in the plan view.

In addition, the alignment hole KH may be located between the third metal pattern ST3 and the fourth metal pattern ST4 in the plan view. For example, the alignment hole KH may be spaced apart from each of the third metal pattern ST3 and the fourth metal pattern ST4 in the plan view. In addition, the one end of each of the alignment patterns may be located between the third metal pattern ST3 and the fourth metal pattern ST4 in the plan view.

As described above, through the alignment patterns, whether the hole area OA is properly formed may be confirmed. For example, light may be irradiated in the third direction DR3 under the substrate SUB. For example, in the first non-display area NDA1 and the hole area OA, light may be irradiated in the third direction DR3 under the substrate SUB. the light may pass through the display device (e.g., the display device DD of FIG. 3) from below the substrate SUB. In this case, the light irradiated from below the substrate SUB in the third direction DR3 may not pass through the alignment patterns including a metallic material. Accordingly, when the first non-display area NDA1 and the hole area OA are viewed on the display device, a portion where the alignment patterns are located may look darker than a portion where the alignment patterns are not located. In this way, when the first non-display area NDA1 and the hole area OA are viewed on the display device, positions of the alignment patterns may be confirmed by checking a portion that looks dark and a portion that does not look dark. It is possible to check whether the hole area OA is properly formed through positions of the alignment patterns.

In this case, the light irradiated from below the substrate SUB in the third direction DR3 may not transmit even the metal patterns including the metal material. In addition, the light irradiated from below the substrate SUB in the third direction DR3 may not transmit even the third layer D1_L3 of the first dam DAM1 including the light blocking material including the black pigment, the black dye, and/or the like. Accordingly, when viewing the first non-display area NDA1 and the hole area OA on the display device, it may be unclear whether a dark-looking portion is a portion where the alignment patterns are located, a portion where the metal patterns are located, or a portion where the third layer D1_L3 is located. That is, recognition rate of the alignment patterns may be lowered.

According to some embodiments, the one end of each of the alignment patterns may overlap the alignment hole KH in the plan view. For example, the one end of each of the alignment patterns may overlap the alignment hole KH, that a portion of the third layer D1_L3 is removed, in the plan view. Accordingly, when the first non-display area NDA1 and the hole area OA are viewed on the display device, recognition rates of the alignment patterns may be improved. In addition, the one end of each of the alignment patterns may be located at a portion where the metal patterns are not located in the plan view. For example, as illustrated in FIG. 6, the one end of each of the alignment patterns may be located between the third metal pattern ST3 and the fourth metal pattern ST4 in the plan view. Accordingly, when the first non-display area NDA1 and the hole area OA are viewed on the display device, recognition rates of the alignment patterns may be improved. Therefore, it is possible to easily check whether the hole area OA is properly formed using the alignment patterns.

FIG. 7 illustrates an example in which the alignment hole KH has a ring shape surrounding the hole area OA, but embodiments according to the present disclosure are not limited thereto, and the alignment hole KH may be formed only at a portion where the alignment patterns are located. For example, the alignment hole KH may include a first portion overlapping the first alignment pattern KP1 and the second alignment pattern KP2 in the plan view, a second portion overlapping the third alignment pattern KP3 and the fourth alignment pattern KP4 in the plan view, a third portion overlapping the fifth alignment pattern KP5 and the sixth alignment pattern KP6 in the plan view, and a fourth portion overlapping the seventh alignment pattern KP7 and the eighth alignment pattern KP8 in the plan view. The first portion, the second portion, the third portion, and the fourth portion may be spaced apart from each other in the plan view. Even when the alignment hole KH is formed only at a portion where the alignment patterns are located, recognition rates of the alignment patterns may be improved.

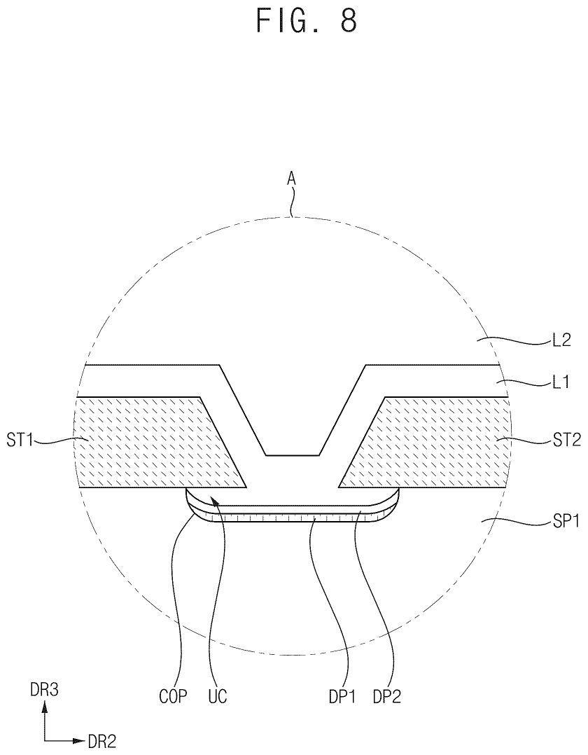

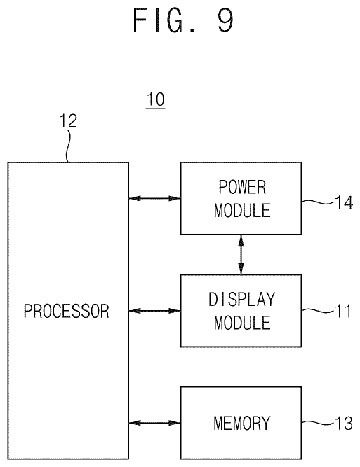

FIG. 8 is an enlarged cross-sectional view of an area A of FIG. 6.

Referring to FIGS. 6 and 8, as described above, the first metal pattern ST1 may cover a portion of the first insulating pattern SP1. In addition, the second metal pattern ST2 may cover a portion of the first insulating pattern SP1. According to some embodiments, a cutout portion COP may be defined on an upper surface of the first insulating pattern SP1. The cutout portion COP may be a portion obtained by removing a portion of the first insulating pattern SP1 from the upper surface of the first insulating pattern SP1. The cutout portion COP may include an undercut area UC. For example, an undercut area UC may be formed in the cutout portion COP. The undercut area UC may be formed such that one end of each of the first metal pattern ST1 and the second metal pattern ST2 is spaced apart from the first insulating pattern SP1. For example, the undercut area UC may be formed such that one end of each of the first metal pattern ST1 and the second metal pattern ST2 is spaced apart from the first insulating pattern SP1 in the third direction DR3.

A first dummy pattern DP1 and a second dummy pattern DP2 may be located in the cutout portion COP. The first dummy pattern DP1 may be formed as the pixel electrode PE has a structure that is separated (or disconnected) by the first insulating pattern SP1, the first metal pattern ST1, and the second metal pattern ST2. For example, the first dummy pattern DP1 may be formed as the pixel electrode PE has a structure that is separated (or disconnected) by the cutout portion COP including the undercut area UC. For example, the first dummy pattern DP1 and the pixel electrode PE may include substantially a same material, and may be formed through substantially a same process as the pixel electrode PE. The first dummy pattern DP1 may be omitted. The second dummy pattern DP2 may be located on the first dummy pattern DP1. The second dummy pattern DP2 may be formed as the light-emitting layer EML has a structure that is separated (or disconnected) by the first insulating pattern SP1, the first metal pattern ST1, and the second metal pattern ST2. For example, the second dummy pattern DP2 may be formed as the light-emitting layer EML has a structure that is separated (or disconnected) by the cutout portion COP including the undercut area UC. For example, the second dummy pattern DP2 and the light-emitting layer EML may include substantially a same material, and may be formed through substantially a same process as the light-emitting layer EML. As the light-emitting layer EML and the second dummy pattern DP2 are separated (or disconnected), impurities or contaminants such as moisture may be prevented from penetrating from the hole area OA into the display area (e.g., the display area DA of FIG. 5). For example, as the display device includes the insulating patterns and the metal patterns, impurities or contaminants such as moisture may be prevented from penetrating from the hole area OA into the display area. The first inorganic encapsulation layer L1 may cover the first metal pattern ST1, the second metal pattern ST2, and the second dummy pattern DP2. The organic encapsulation layer L2 may cover the first inorganic encapsulation layer L1. Although FIG. 8 may illustrate a structure of the first insulating pattern SP1, embodiments according to the present disclosure are not limited thereto, and each of the second insulating pattern SP2, the third insulating pattern SP3, the fourth insulating pattern SP4, the fifth insulating pattern SP5, and the sixth insulating pattern SP6 may have substantially a same structure as the first insulating pattern SP1 of FIG. 8.

The display device (e.g., the display device DD of FIG. 1) according to embodiments may be applied to various electronic devices. An electronic device according to embodiments may include the above-described display device, and may further include a module or device having other additional functions in addition to the display device.

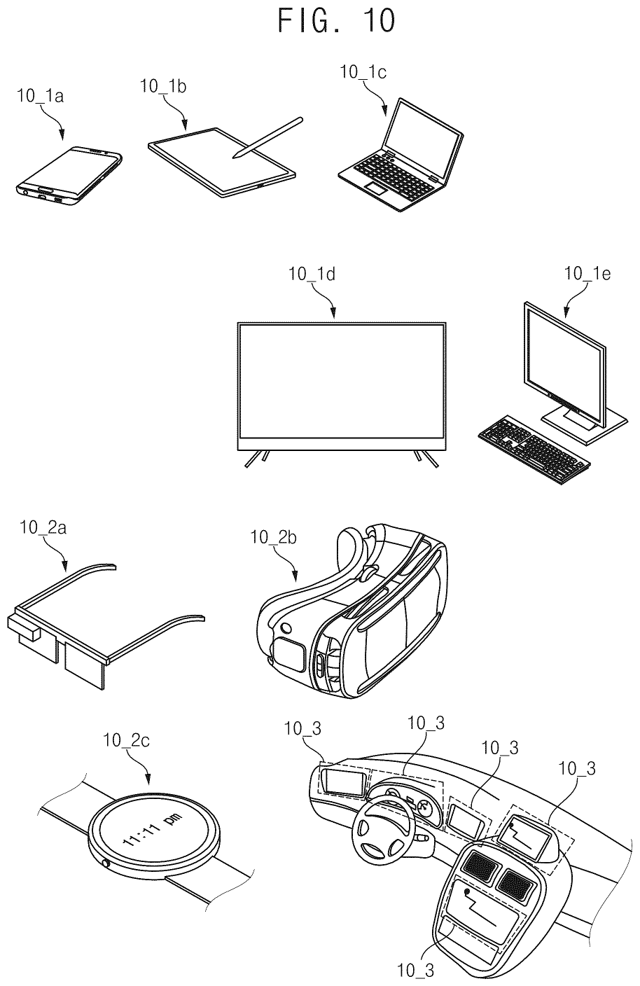

FIG. 9 is a block diagram illustrating an electronic device according to embodiments.

Referring to FIG. 9, an electronic device 10 according to embodiments may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), or a controller.

Data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

FIG. 10 is a schematic diagram of an electronic device according to various embodiments.

Referring to FIG. 10, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) located on a dashboard, a room mirror display, and/or the like.

The present disclosure can be applied to various display devices. For example, embodiments according to the present disclosure are applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a hole area, a first non-display area surrounding at least a portion of the hole area, and a display area surrounding at least a portion of the first non-display area;
pixels in the display area on the substrate;
a first dam in the first non-display area on the substrate, wherein the first dam includes an alignment hole; and
a first alignment pattern in the first non-display area on the first dam, wherein the first alignment pattern at least partially overlaps the alignment hole in a plan view.

2. The display device of claim 1, wherein the alignment hole overlaps one end of the first alignment pattern in the plan view.

3. The display device of claim 1, wherein the first dam has a ring shape surrounding the hole area.

4. The display device of claim 3, wherein the alignment hole has a ring shape surrounding the hole area.

5. The display device of claim 1, wherein each of the pixels includes a light-emitting element including a first electrode, a light-emitting layer on the first electrode, and a second electrode on the light-emitting layer, and
the display device further comprises:
a pixel defining layer covering a side portion of the first electrode.

6. The display device of claim 5, wherein the first dam includes,
a first layer;
a second layer on the first layer; and
a third layer on the second layer and including a same material as the pixel defining layer.

7. The display device of claim 6, wherein the third layer of the first dam defines the alignment hole.

8. The display device of claim 5, further comprising:
an input electrode on the light-emitting element, and
wherein the first alignment pattern and the input electrode are in a same layer.

9. The display device of claim 1, further comprising:
a second dam located in the first non-display area and spaced apart from the first dam in the plan view.

10. The display device of claim 1, further comprising:
a second alignment pattern spaced apart from the first alignment pattern and at least partially overlapping the alignment hole in the plan view, and
wherein the hole area is between the first alignment pattern and the second alignment pattern.

11. The display device of claim 10, wherein the alignment hole overlaps one end of the second alignment pattern in the plan view.

12. The display device of claim 10, further comprising:
a third alignment pattern spaced apart from each of the first alignment pattern and the second alignment pattern in the plan view and at least partially overlapping the alignment hole in the plan view; and
a fourth alignment pattern spaced apart from the third alignment pattern and at least partially overlapping the alignment hole in the plan view, and
wherein the hole area is between the third alignment pattern and the fourth alignment pattern.

13. The display device of claim 1, wherein the substrate further includes a second non-display area surrounding at least a portion of the display area and in which a driver is located.

14. The display device of claim 1, further comprising:
an insulating pattern in the first non-display area and spaced apart from the first dam in the plan view; and
a metal pattern covering at least a portion of the insulating pattern.

15. The display device of claim 14, wherein one end of the metal pattern and the insulating pattern are spaced apart to form an undercut area.

16. The display device of claim 14, wherein the alignment hole and the metal pattern are spaced apart from each other in the plan view.

17. A display device comprising:
pixels in a display area;
a component spaced apart from the pixels in a plan view;
a dam surrounding at least a portion of the component, wherein the dam includes an alignment hole; and
a first alignment pattern at least partially overlapping the alignment hole in the plan view.

18. The display device of claim 17, wherein the alignment hole overlaps one end of the first alignment pattern in the plan view.

19. The display device of claim 17, further comprising:
a second alignment pattern spaced apart from the first alignment pattern and at least partially overlapping the alignment hole in the plan view,
wherein the component is between the first alignment pattern and the second alignment pattern.

20. An electronic device comprising:
a substrate including a hole area, a first non-display area surrounding at least a portion of the hole area, and a display area surrounding at least a portion of the first non-display area;
pixels in the display area on the substrate;
a first dam in the first non-display area on the substrate, wherein the first dam includes an alignment hole;
a first alignment pattern in the first non-display area on the first dam, wherein the first alignment pattern at least partially overlaps the alignment hole in a plan view; and
a memory configured to store data information.
